(19) United States
(12) Patent Application Publication
(10) Pub. No.: US 2026/0202490 A1
(43) Pub. Date: Jul. 16, 2026

(54) THERMAL IMPEDANCE MONITORING PROCESS FOR POWER MODULE

(71) Applicant: MITSUBISHI ELECTRIC CORPORATION, TOKYO (JP)

(72) Inventors: Pierre-Yves PICHON, RENNES Cedex 7 (FR); Julio BRANDELERO, RENNES Cedex 7 (FR)

(73) Assignee: MITSUBISHI ELECTRIC CORPORATION, TOKYO (JP)

(21) Appl. No.: 19/135,308

(22) PCT Filed: Aug. 7, 2023
(86) PCT No.: PCT/JP2023/029389

§ 371 Date: Jun. 3, 2025

(30) Foreign Application Priority Data
Dec. 19, 2022 (EP) 22306944.4

(51) Int. Cl. G01R 31/40; H02M 1/32; H02M 7/5387

(52) U.S. Cl. CPC G01R 31/40; H02M 1/327; H02M 7/5387

(57) ABSTRACT

Thermal impedance monitoring process for a power module of a power converter used for transforming DC current to AC current, or vice-versa, said power module comprising at least a semiconductor die attached to a material stack-up of layers, said process comprising:
sampling and measuring a signal relating to the junction temperature of said semiconductor die at a frequency higher than twice said AC frequency of said AC current,
calculating a time duration between a moment where said junction temperature of said semiconductor die is at a maximum value, and a moment where said junction temperature is at a minimum value, in one period of said AC current,
repeating said sampling and measuring said signal and said calculating said time duration at different times and comparing said time durations for monitoring said time duration to determine degradation of the thermal impedance of said power module.

### TECHNICAL FIELD

The present disclosure is in the field of protecting power semiconductor modules from failures due to overheating in particular overheating due to thermal interfaces degradation and maintenance of equipment using such modules.

### BACKGROUND ART

Thermal interfaces degradation in a power module is due to delamination and void creation in any of the substructures between a semiconductor die and a heatsink. These degradations increase temperature of the semiconductor die that can lead to an unsafe temperature operation region. The consequence of the high temperature is the semiconductor breakdown and power module failure. Monitoring the thermal interfaces is then important to maintain the power module in a safe temperature region and guide maintenance and replacement phases of the power module.

The degradation phenomena are caused by the temperature swing and the CTE mismatch between the different materials composing a power module stack-up shown in FIG. 1 that includes at least: semiconductor die 3 (for example in silicon), die attach 4 (for example in solder), a conductive layer 6 (for example in copper), an electrical insulator layer 7, and a heat-sink 8 (for example in aluminum).

The power module 1, can also comprise elements such: a thermal conductive layer 9 (for example in copper), a join layer 10 (for example solder), a base plate 11 (for example copper), a thermal interface 12 (for example graphite or thermal paste). A symmetric material stack-up can be also envisaged in the case of a double side cooling where the stack-up present hereinbefore is repeated on the top side 5 of the semiconductor die 3.

FIG. 2 shows possible cracks 2 in a layer such as layer 4. Such cracks cause a reduction of the thermal conduction of the layer.

In document Broeck & al. “In situ thermal impedance spectroscopy of Power electronic modules for localized degradation identification”, PCIM Europe 2019; International Exhibition and Conference for Power Electronics, Intelligent Motion, Renewable Energy and Energy Management, 07-9 May 2019 Nuremberg, Germany; VDE ISBN: 978-3-8007-4938-6, is disclosed a method to extract the thermal impedance frequency response function of power modules without interrupting normal converter operations. A sinusoidal small-signal loss excitation to a power device, extracts the temperature response of such power device and correlates both signals to estimate the thermal impedance at the excitation frequency. The method relies on phase information rather than magnitude, and thus is insensitive to measurement errors in loss and/or temperatures. It requires a small signal loss excitation method that will impact on torque ripple for a motor driver application for example.

In document Polom & al., “Real-Time, In Situ Degradation Monitoring in Power Semiconductor Converters” 2019 IEEE Applied Power Electronics Conference and Exposition (APEC), 17-21 Mar. 2019, IEEE, DOI: 10.1109/APEC.2019.872182 the spatiotemporal dynamic thermal response of a semiconductor assembly response change with degradation is measured with a heat injection having a certain frequency content (sinus and square). The temperature of the semiconductor die is estimated via TSEP (thermal sensitive electrical parameter), the frequency response function (FRF) is computed for each system identification experiment, the FRF segments are combined and a function model is interpreted for thermal interface degradation.

In the document Xiang & al., “Condition Monitoring Power Module Solder Fatigue Using Inverter Harmonic Identification”, IEEE Transactions on Power Electronics, Volume: 27, Issue: 1, January 2012 Pages 235-247, DOI: 10.1109/TPEL.2011.2160988, a method to monitor solder fatigue in an inverter applying IGBT power module is described to detect the change of the output harmonic. It is shown that low-order harmonics, caused by nonideal switching, are affected by the device junction temperature, which in turn depends upon module solder condition. The method lacks on accuracy; thus, the inverter controller is set to cause harmonic resonance at a given frequency.

The standard JESD51-14 describe a method to measure the ‘transient measurement of thermal resistance’. The method consists of measuring the junction temperature preferably after the heating power is switched off (cooling curve). Although not recommended, in principle also the heating curve can be used if there is a constant heating power during the heating pulse time. In the first case, the measurement obliges the power module to be turned-off after being worked in a known and thermal steady-state condition. In both cases, the power losses should be known, which is hardily estimated during the on-line operation (in field application).

Thermal impedance measurements techniques are powerful transient thermal response techniques which can give information on the degradation of the different interfaces of the power module. The technique typically consists in:

First, applying a starting steady-state thermal condition on the power module using the semiconductor switch as active devices. This starting condition can either be a zero-power condition, or a condition where a known and measured constant power is dissipated at the semiconductor.

Second, applying a controlled power step increase (in case the start condition is a zero-power condition) or a power step decrease (in case the start condition is a constant power condition), and then recording the evolution of the semiconductor temperature until the new steady state thermal condition is reached.

Finally, the recorded temperature transient behavior is described by using an equivalent Foster and Cauer network which represent the thermal structure of the power module by several RC elements. A fitting of the temperature transient using the foster equation allow to extract the resistances and capacitances of the different part of the power module, giving information of the evolution of thermal resistances and capacitances.

Lock-in thermography techniques are well-proven commercially available techniques to detect material and system damages (e.g. delamination cracks in composites, voids, etc. . . . ) as discussed in Gerd Busse “Lockin-Thermography: Principles”, NDE-applications and trends, January 2014 Conference: 2014 Quantitative InfraRed Thermography, DOI: 10.21611/qirt.2014.e.

The lock-in thermography techniques uses a process where the material or system to be analyzed thermally is excited with a non-steady state signal (e.g a pulsed signal, or a sinusoidal signal) at a specific frequency (related to the material thickness or damage depth), for example using an infrared radiative source such as a set of halogen lamps, recording images of the transient temperature response of the system/material, using specific software and algorithm, calculating the phase and the amplitude between the response and the excitation, and thus generating a phase image and an amplitude image. These techniques are used in thermal steady state conditions.

Problems with respect to the state-of-the-art methods for thermal impedance monitoring are that:
The dissipated power in the semiconductor must be known, i.e., it must be measured or estimated. In cases where the semiconductor is integrated in a power converter, this can be a difficult task;
with the thermal measurement techniques described above, where the measurements are done in a steady state thermal situation) no information can be gained on which of the layers of the power module stack-up is degraded.

### SUMMARY OF INVENTION

The present disclosure proposes a measurement method using a lock-in technique in transient states instead of steady state situations.

More precisely, the present disclosure proposes a thermal impedance monitoring process for a power module of a power converter used for transforming DC current to AC current, or vice-versa, where the semiconductor dissipates an asymmetrical loss between two half cycles of an AC frequency f of the AC current, said power module comprising at least a semiconductor die attached to a material stack-up of layers for its thermal dissipation and/or electrical connections, said process comprising:
sampling and measuring a signal relating to the junction temperature Tj of said semiconductor die at a frequency higher than ten time said AC frequency of said AC current,
calculating a time duration Δt=tTjmax−tTjmin between a moment tTjmax, where said junction temperature of said semiconductor die is at a maximum value, and a moment tTjmin, where said junction temperature is at a minimum value, in one period of said AC current, and storing said time duration Δt in a memory,
repeating said sampling and measuring said signal and said calculating said time duration at different times tₓ=t₀ to tₚ during the operating life of the power module to provide a series of time durations Δtₜ₀ to Δtₜₚ, and comparing said time durations Δtₜₚ values with Δtₜ₀ for monitoring an evolution of said time duration Δtₓ to determine an evolution of degradation of the thermal impedance of said power module.

The process may comprise measuring said AC frequency and storing couple of time duration Δtₜₓ and AC frequency, f_{fund} values.

The process may comprise modifying said AC frequency during dedicated operation periods of said converter to provide several different AC frequencies fₘ=f₁, f₂, . . . , fₙ each allowing to detect a thermal impedance of a specific layer of said stack up, repeating said sampling and measuring and said calculating the time durations Δt_{txf1}, Δt_{txf2}, . . . , Δt_{txfn} corresponding to such different AC frequencies,
repeating said sampling and measuring said signal and said calculating said time duration during the operating life of the power module to provide a series of Δt₀ to Δtₓ values for each of said different AC frequencies, and comparing said Δt_{txfm} values with Δtₜ₀fₘ at each of said AC frequencies fₘ=f₁, f₂, . . . , fₙ for monitoring an evolution of Δ_{txfm} for each of said AC frequencies to determine an evolution of degradation of the thermal impedance of said specific layers.

The process may comprise measuring a time difference Δtmin between two successive minima of the junction temperature and calculating said AC frequency as f=1/Δtmin.

The signal relating to the junction temperature Tj may be a temperature sensitive electrical parameter of said semiconductor.

In such case the signal may be a non-calibrated temperature sensitive electrical parameter of said semiconductor.

Said AC frequency may be lower than

$${f}_{d} = \frac{{D}_{d i e}}{{l}_{die}^{2}}$$

where l_{die} is the die thickness and D_{die} is the diffusivity coefficient of the die.

Said AC frequency may be lower than 2 kHz.

Said AC frequency may be lower than 1 kHz.

Said AC frequency may be the fundamental frequency powering the converter or the fundamental output frequency f_{fund} of the converter.

The present disclosure concerns also a converter comprising sensor means on a power semiconductor switch die of said converter for sensing a temperature on said power semiconductor switch die, analog to digital converter means, sampling means and a processor provided with memory means for storing and running a software configured for executing the thermal impedance monitoring process described hereabove. In particular, said sensor means may be designed to sense a temperature sensitive electrical parameter of said die. The present disclosure proposes also a software comprising instructions for executing the thermal impedance monitoring process disclosed hereabove.

A detailed description of exemplary embodiments of the disclosure will be discussed hereunder in reference to the attached drawings.

### BRIEF DESCRIPTION OF DRAWINGS

FIG. 1 is an example of traditional stack of layers for a power module.

FIG. 2 is a view of a cracked solder layer.

FIG. 3 is a prior art diagram of surface temperature response phase shift versus depth of a defect.

FIG. 4 is a Cauer network example of a stack-up of a power module.

FIG. 5 is a first Bode diagram for a first example of defects layers of a stack-up.

FIG. 6 is a second Bode diagram for a second example of defects layers of a stack-up.

FIG. 7 is a third Bode diagram for a third example of defects layers of a stack-up.

FIG. 8 is an expanded Bode diagram for the first example of defects layers of the stack-up of FIG. 5.

FIG. 9 is a simplified schematic view of a converter example with processor.

FIG. 10A is a diagram of losses and junction temperature versus time for a pristine and a degraded stack-up.

FIG. 10B is a diagram of losses and junction temperature versus time for a pristine and a degraded stack-up.

FIG. 11 shows the losses waveforms for different modulation types in a DC/AC converter according to different controls.

FIG. 12 shows a diagram of equivalent phase shift versus fundamental frequency for different degradations of layers.

FIG. 13A shows process steps of the present process.

FIG. 13B shows process steps of the present process.

FIG. 13C shows process steps of the present process.

### DESCRIPTION OF EMBODIMENTS

In order to characterize the behavior of a power module, the thermal wave theory predicts that the thermal response of the surface of a homogeneous infinite material half-space subjected to a thermal excitation P₀=P₀ (1+cos(ωt))/2 is shifted by

$$+ \frac{π}{4}$$

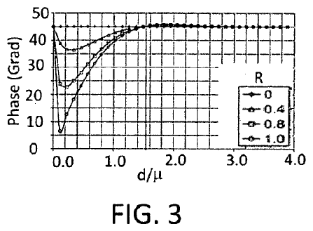

(+40°). Because of the wave nature of the excitation heat propagation within the material can be analyzed from wave theory, in which a defect or interface present at a distance d under the surface of the material can be modelled by a reflection coefficient R (0<R<1) for the thermal waves and will change the phase of thermal response of the surface, compared to the semi-infinite body case. The reflection coefficient is function of the material properties and of the contact resistance between the different materials, in case voids or defects are present at the interface. The reflection coefficient is also frequency dependent. The curves in FIG. 3 show the effect of a defect of strength R positioned a depth d on the phase shift of the surface temperature response as disclosed in document Rigert “Induktions-Lockin-Thermografie: ein neues Verfahren zur zerstörungsfreien Prüfung” http://dx.doi.org/10.18419/opus-1734. This chart shows the influence of the defect depth d (normalized with μ, a material parameter), and the reflection coefficient R (R=0=> no defect (perfect transmission); R=1=> strong defect (perfect reflection)).

It can be seen that when a defect is positioned at d<1.55 μm and has a coefficient of reflection R>0.4, the surface temperature response phase shift changes from the semi-infinite body value of 45° to a lower value that depends on R and on the position of the defect.

FIG. 3 thus shows the basic principle of lock-in thermography to characterize defects and interfaces in materials, devices including a module stack-up.

Importantly the value of μ is frequency dependent: for defects located further into the material, greater sensitivity is obtained when lower excitation frequency is used. Thus, by varying the excitation frequency, information about interface (degradation) of different layer stack or interface can be gained.

Although this simple model can give a good guidance on methods using thermal waves to detect damage, a power semiconductor stack cannot be modelled by a semi-infinite body, due to the different thermal properties of each layer of the stack. In order to analyze this system more precisely a 1D electrical equivalent of the thermal model can be used, one which the frequency response function can by analyzed.

### Thermal Impedance: Electrical Equivalent Model:

On the basis that heat conduction and electronic conduction are both physical processes modelled by the same phenomenon (diffusion), the thermal impedance of a semiconductor module can be modelled by analogy with the scaled heat conduction equation and the telegrapher's equations. Thus, an equivalent electrical network of the thermal system can be deduced. The resistances and capacitances of the electrical equivalent are defined by analogy with a thermal resistance, Rth and capacitance Cth, using the following equations:

$$R t h = \frac{Δ T}{ϕ} = \frac{l}{λ \cdot A} \qquad ( 1 )$$

Where l is the thickness;
A is the cross section area;
λ is the thermal conductivity,

$$C t h = \frac{E t h}{Δ T} = c \cdot ρ \cdot V \qquad ( 2 )$$

Where c is the specific heat capacity [J/g];
V is the volume [m³];
ρ is the density [g/m³].

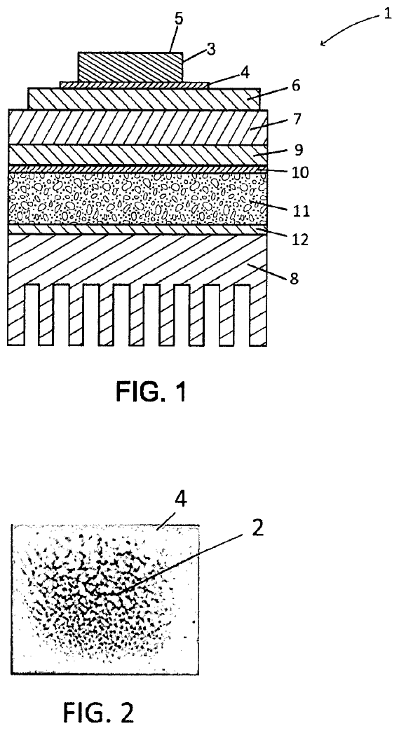

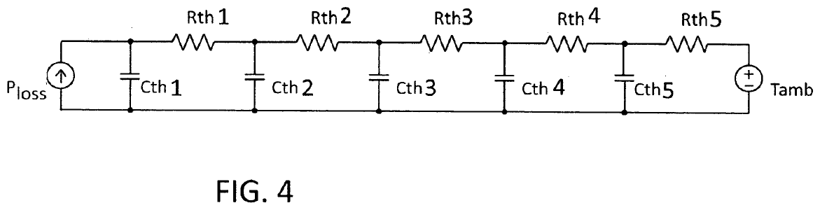

In the case of a simple model of power module composed with a stack-up of different materials, each layer will present a thermal resistance and a thermal capacitance. Thus, an electrical network, called Cauer network, can represent the thermal system of a stack-up of 5 layers as shown in FIG. 4. Pₗₒₛₛ is the heat flux from the semiconductor die 5 of FIG. 1, corresponding to the losses dissipated on the semiconductor die (the electrical equivalent is a current source), Cₜₕ and Rₜₕ are the equivalent capacitance and resistance of each layer starting with the die layer 3 and the heatsink layer 5 and Tamb is the environment heatsink temperature.

The total thermal impedance of the network of FIG. 4 can be calculated using the following equation where s is the Laplacian operator:

$$Z ( s ) = \frac{1}{\begin{matrix}s \cdot {Cth}_{1} + \\ \frac{1}{\begin{matrix}{Rth}_{1} + \\ \frac{1}{\begin{matrix}s \cdot {Cth}_{2} + \\ \frac{1}{{Rth}_{2} + \frac{1}{s \cdot {Cth}_{3} + \frac{1}{{Rth}_{3} + \frac{1}{s \cdot {Cth}_{4} + \frac{1}{{Rth}_{4} + \frac{1}{s \cdot {Cth}_{5} + \frac{1}{{Rth}_{5}}}}}}}}\end{matrix}}\end{matrix}}\end{matrix}} . \qquad ( 3 )$$

For the case of a degraded layer, a new (increased) resistance R_{th,v} may be calculated using a percentage of void, f, as described in the next equation. As the material quantity is not modified, the thermal capacitance Cth remains unchanged:

$${R}_{th , v} = \frac{R t h}{{( 1 - f )}^{2}} . \qquad ( 4 )$$

For example, in the case of the stack-up of nine layers described in FIG. 1 and the material data of Table 1 hereunder:

TABLE 1

| Stack up layers | λ [W/mK] | ρ [g/cm³] | c [J/gK] | l [mm] |
|---|---|---|---|---|
| 3 (silicon) | 80 | 2.3 | 0.712 | 0.14 |
| 4 (die attach) | 50 | 7.4 | 0.24 | 0.1 |
| 6 | 404 | 8.9 | 0.385 | 0.3 |
| 7 | 160 | 3.3 | 0.72 | 0.7 |
| 9 | 450 | 8.9 | 0.385 | 0.32 |
| 10 | 60 | 7.4 | 0.24 | 0.4 |
| 11 | 450 | 8.9 | 0.385 | 4 |
| 12 | 30 | 1.81 | 0.85 | 0.15 |
| 8 | 239 | 2.7 | 0.921 | 20 |

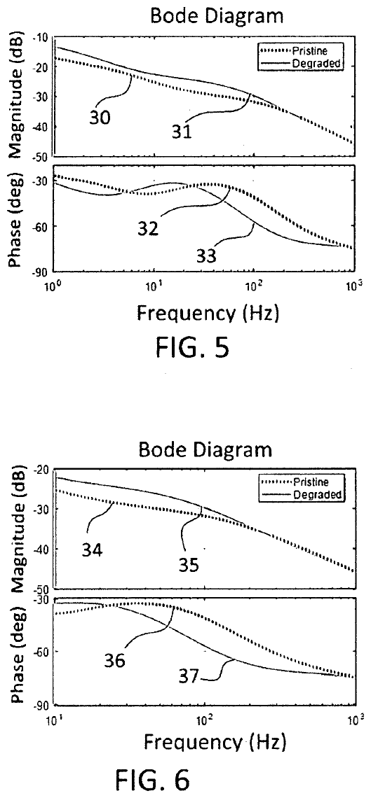

The thermal impedance may be plotted in a bode diagram, where the amplitude and the phase are plotted in function of the excitation frequency of a sinus type. In the curves of FIGS. 5 to 7 a comparison is done between a pristine, that is non-degraded module, and a degraded module according to FIG. 1 with measurements done at increasing frequencies.

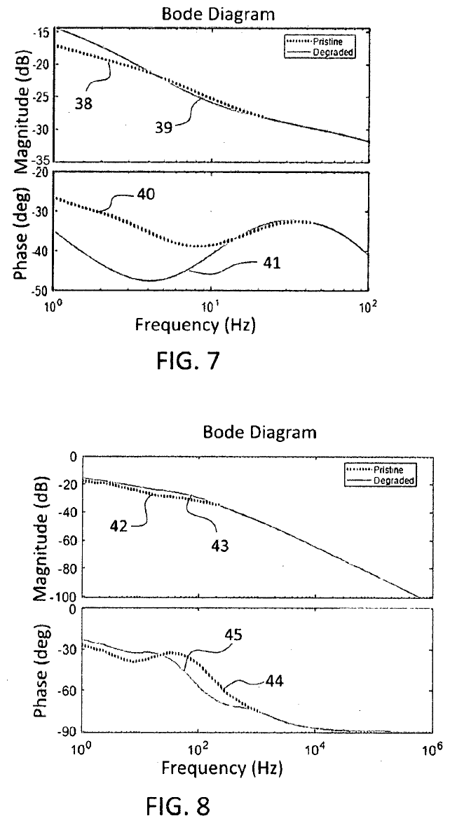

FIG. 5 is the Bode diagram of a stack according to FIG. 1 with the layer 4 and the layer 10 having 40% of voids. FIG. 6 is the Bode diagram of a stack according to FIG. 1 with the layer 4 has 40% of voids. FIG. 7 is the Bode diagram of a stack according to FIG. 1 with the layer 10 has 40% of voids. These figures show that the amplitude and the phase of the thermal impedance are modified by the degradation.

Curves 32, 33 of FIG. 5, curves 36, 37 of FIG. 6 and curves 40, 41 of FIG. 7 are representing the phase difference between the temperature variations of the die for of pristine in dotted line and degraded layers in plain lines. Curves 30, 31 of FIG. 5, curves 34, 35 of FIG. 6 and curves 38, 39 of FIG. 7 are representing the amplitude of the temperature variation of the die with pristine in dotted line and degraded layers in plain lines.

The influence of a degradation of layer 4 which is located close to the excitation source can best be detected by a phase shift of curve 33 with respect to curve 32 at about 100 Hz excitation as in FIGS. 5 and 6, whereas a relatively lower excitation frequency from about 1 to 10 Hz is required to detect a frequency shift between curve 40 and curve 41 corresponding to a damage in layer 10 which is located further away from the heat source as seen in FIG. 7. Note that no phase shift change is observed at 100 Hz in case damage is introduced in layer 10. Thus, by varying the excitation frequency, it is possible to gain information on which layer is damaged.

### Power Semiconductors Die Losses:

The previous section described the thermal response of the system to a sinusoidal excitation. In real application cases the power dissipation does not necessarily follow a sinusoidal behavior. The goal of this section is to describe the necessary conditions of the semiconductor operating point that generate a suitable thermal response of the system such that an information on a layer degradation can be gained. To support the loss profile requirements, the bode diagram of FIG. 6 is plot on a larger frequency range as in FIG. 8 where the interval goes from 1 Hz to 1 MHz.

In the present example, FIG. 8 shows the following information:
The magnitude of the bode diagram gives essentially the same information as a thermal impedance plot;
The phase information shows that the curves 42, 44 of non-degraded and the curves 44, 45 of degraded cases merge at f>1 kHz. Thus, no information on the degradation can be gained by analysing the phase response of the system above this frequency.

The reason why the degraded and non-degraded cases cannot be separated at f>1 KHz is because in the high frequency range the thermal impedance of the heat source (the silicon die) acts as a filter to the electrical excitation. This is straightforward when noticing that the thermal response timescale of the die is of order of τ_{d}=Rth_{d} Cth_{d}. Using the definitions:

$${τ}_{d} = R t {h}_{d} C t {h}_{d} = \frac{l}{λ \cdot A} . c \cdot ρ \cdot V = \frac{l}{λ \cdot A} . c \cdot ρ \cdot A . l = \frac{{l}^{2} c \cdot ρ}{λ} = \frac{{l}_{d}^{2}}{{D}_{d}} . \qquad ( 5 )$$

In diffusion theory

$$D = \frac{λ}{c \cdot ρ} ( unit : [ \frac{J . {m}^{3} g . K}{s . m . K . g . J} ] = [ \frac{{m}^{2}}{s} ] )$$

is called the diffusivity coefficient.

$${τ}_{d} \approx \frac{{l}_{d}^{2}}{{D}_{d}}$$

is the timescale needed for a heat pulse to travel through the die thickness l_{die}.

Using the values of material 3 in Table 1 we find

$${D}_{d} = 4.88 {10}^{- 5} \frac{{m}^{2}}{s} ,$$

using a die thickness l_{d}=0.14 mm; τ_{d}=4.01 10⁻⁴ s. The thermal system response bandwidth is thus limited by

$${f}_{d} = \frac{1}{{τ}_{d}} = 2.5 kHz ,$$

which is the same order of magnitude as the 1 kHz value found by examination of the bode diagram in FIG. 8.

The implication for the applicability of this invention is thus that the electrical excitation frequencies of interest should be significantly lower than

$${f}_{d} = \frac{{D}_{s i}}{{l}_{d}^{2}} ;$$

i.e., preferably lower than 2 kHz and preferably lower than 1 kHz.

Advantageously to the present invention, typical signal modulation strategies such as PWM modulation in converters typically operate at frequencies higher than 1 kHz, such as 5 kHz, or 10 kHz. In consequence, the thermal system response will be weak in this frequency range, and the temperature oscillations due to the PWM frequency will be weak as seen in the magnitude of the bode plot <−60 dB of FIG. 8. Thus, advantageously, the thermal system will not be influenced by the PWM excitation. For the use of the model described in the previous section this justifies that the losses can be averaged over a PWM period.

Advantageously to the present invention, typical excitation frequencies may be limited by the load impedance, by the load requirements, or by the external control of the system, such that the system is typically excited in the frequency range of interest, i.e., at a frequency lower than 1 kHz, for example 50 Hz, 60 Hz, 100 Hz, 400 Hz, or 1 Hz.

Another implication of this analysis is that a low frequency electrical excitation signal should not decrease from the maximum power value to the zero-power value within a time interval lower than ta.

Thus, to summarize the power semiconductor losses requirements within the present invention: the power semiconductor die losses waveform is dependent on the application where the power module or system is installed.

This invention relates to the cases of DC/AC or AC/DC power converter topologies, and to the cases where the losses are low frequency periodic pulsating waves with the following characteristics:
a. A maximum pulse duration of a half-period of the fundamental frequency of the AC current, such that there exists a zero-loss time interval.

### AND

b. At least one local maximum inside the pulse, OR an asymmetrical loss dissipation between the two half-cycles.

### AND

c. The time difference between the last maximum and the zero-loss time is larger than

$${τ}_{d} = \frac{{l}_{d}^{2}}{{D}_{d}} ,$$

where l_{d} is the thickness of the semiconductor chip, and D_{d} is the heat diffusivity of the semiconductor chip. This implies the low frequency of the modulated losses to be lower than

$${f}_{d} = \frac{{D}_{d i e}}{{l}_{die}^{2}}$$

where ldie is the die thickness and Ddie is the diffusivity coefficient of the die.

As an example, for condition c, the semiconductor chip is a silicon chip of thickness l_{die}=100 μm, the thermal diffusivity coefficient of silicon is D_{die}=4.89 10⁻⁴ m²/s, and thus f_{die}=4.89 kHz, and τ_{die}=205 μs.

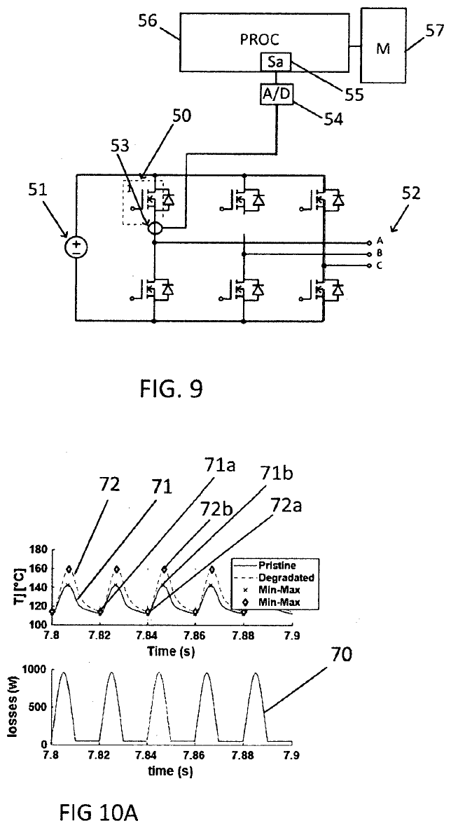

An example of DC/AC power topology is shown in FIG. 9 where a DC supply 51 serves to build a three-phase alternating supply 52 using power semiconductor switches 1. The DC/AC power converter has a 3-phase configuration supplied by a DC bus voltage. The semiconductor die can be any IGBT, Diode, MOSFET, MISFET and in any placement of the power converter topology. In the following example, the semiconductor die of interest in the power module is placed in one leg at the high side position.

The switching and conduction losses of the semiconductor die 50 are generated in a normal operation of the power module in a motor control application given the load current, the bus voltage during the switching and conduction events.

The semiconductor die losses generation in a power module on a DC/AC or DC/AC operation is proportional to the following variables that are related to the operating point: the current passing through I_{cond}, the switched current I_{sw}, the switched voltage V_{sw}, the switching frequency f_{sw}, the junction temperature, Tⱼ, the duty cycle modulation strategy/PWM technique.

In such an application, typically, a periodic pulsed loss waveform in an DC/AC or AC/DC application is generated in the fundamental frequency, e.g., a grid frequency 50 Hz or an electrical motor rotation control frequency of 1 Hz-2 kHz. In any strategy, the losses on the semiconductor are generated only during a time corresponding to a first half-cycle of the fundamental frequency, and the semiconductor does not generate any losses during the second half cycle of the fundamental frequency.

Considering that the power converter generates a sinusoidal current waveform, at the fundamental frequency of 100 Hz, on the output of the phases ABC and a chopped voltage waveform at the switching frequency operation of 20 KHz.

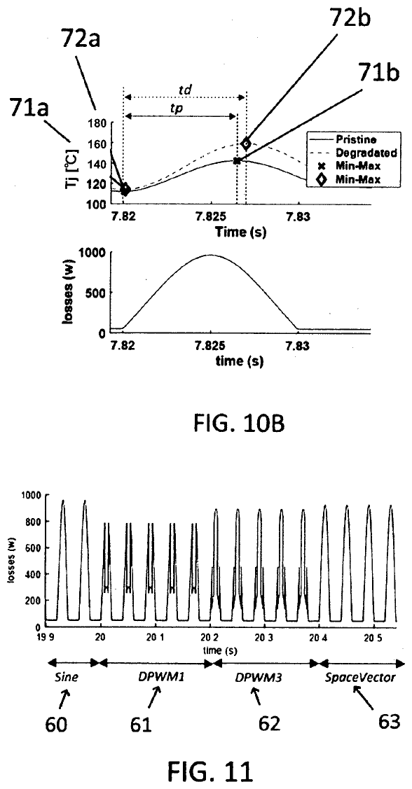

FIGS. 10A and 10B are representation of the junction temperature and losses for a pristine and degraded power module at 100 Hz of fundamental AC frequency. FIG. 10A is a general view of the power and junction temperature waves with respect to time, FIG. 10B is a zoomed figure on one loss period comprising also a measurement of the die temperature Tj duration time. In this example, the losses wave 70 in FIG. 10A on the semiconductor die has only the positive sinusoidal shape. In other words, the losses follow a sinusoidal shape between 0° and 180° (0 and π) and have a null value between 180° and 360° (π and 2π) within the fundamental frequency f_{f}:

$$Ploss \approx \{ \begin{matrix}A \cdot {sin}^{2} ( 2 π \cdot {f}_{f} \cdot t ) & for & 0 \leq 2 π \cdot {f}_{f} \cdot t \leq π \\ 0 & for & π < 2 π \cdot {f}_{f} \cdot t < 2 π\end{matrix} . \qquad ( 6 )$$

The temperature response Tj of the die 71, 72 in FIG. 10A is calculated using the thermal impedance. The temperature wave has one minimum 71a, 72a and one maximum 71b, 72b within a fundamental period. When measuring the time between the minimum temperature point and the maximum temperature point gives an indicator of the module degradation. In FIG. 10B showing a single loss period, it can be seen that the degraded power module with 40% of voids in layer 4 of FIG. 1 operating at 100 Hz of AC current has a longer duration time Δt=td than that of the pristine power module Δt=tp. This can be explained by the bode diagram of FIG. 6, showing a larger absolute phase angle for the degraded thermal impedance compared to the pristine thermal impedance at 100 Hz.

An important point is that it is possible only by examination of the temperature response to identify the beginning of the pulse corresponding to tTjmin, because the sudden power change generates a kink in the temperature response. Thus, advantageously, the information of Δt=tTjmax−tTjmin is related to the phase angle between the temperature response and the power excitation.

FIG. 11 shows the losses in the fundamental frequency of the converter plotted for different modulation strategies when a DC/AC power converter drives an electrical motor. The different modulation strategies are: Sine 60, DPWM1 61, DPWM3 62, Spacevector 63. The losses are calculated considering both the conduction losses and the switching losses of the semiconductor die, and averaged over a modulation period.

The topologies of the converter are not limited to the converter taken as an example but could be multilevel topologies as the NPC (neutral point clamped inverter), ANPC (Active-neutral-point-clamped inverter), MMC (modular multilevel converter), FC (flying capacitor) and other topologies that are the state of art.

This shows that in an AC/DC or DC/AC power converter having a power module comprising at least a semiconductor die attached to a material stack-up for the thermal dissipation and/or for electrical connections, where the semiconductor dissipates an asymmetrical loss between two half cycles of the AC frequency, measuring a signal related to the temperature of the semiconductor at said frequency, measuring the time duration Δt=tTjmax−tTjmin between the temperatures Tjmax and Tjmin where the junction temperature is at the maximum and respectively its minimum value, in an AC period permits to obtain a measurement of the degradation of at least one layer in a stack of layers between the die and a heatsink to which the die is attached by repeating such measurements during life of the power converter.

Thus, advantageously since de degradation is sensitive to the temperature increase time delay Δt, and not to the magnitude of the temperature, nor the magnitude of the power losses the thermal degradation estimation is not sensitive to the accuracy of the junction temperature measurement, and thus any signal related to the temperature of the semiconductor can be used, provided there is a monotonous relation between the temperature and the signal. It is not necessary to estimate or measure the power losses in the semiconductor, thus advantageously reducing the number of sensors, the computation time and increasing the accuracy of the degradation measurement.

In order to repeat measurements and compare such during the life of the converter, the calculations of the temperature increase time delay Δt=tTjmax−tTjmin may be stored in a memory at each iteration and compared with an initial value and/or a previous value and the evolution of such time delay Δt, for tₓ=t₀ to tₚ may be monitored to obtain the degradation state of the thermal impedance.

In addition to the measurement of the temperature increase time delay, the fundamental frequency f_{fund} at which the losses are measured may be measured and stored and the degradation state is determined by the time duration Δt(f_{fund}) at said fundamental frequency.

Thus, advantageously, degradation information of a specific stack layer can be gained, as the variation of the damage indicator Δtₓ is sensitive to the fundamental frequency.

For example, the fundamental loss frequency can be measured using the AC load current probe, or be given by the controller reference, or be given by the user AC frequency request.

As discussed hereunder, damages at different height in the stack causes different phase shift in the temperature increase curves and measuring damage indicators Δti(f_{fund,i}) at different frequencies f_{fund,i} enables to gain information on the degradation evolution at different layers of the stack. The higher frequencies are used to monitor a degradation of the stack layers closer to the semiconductor and the lower frequencies are used to monitor a degradation of the stack layers farther from the semiconductor.

The effect of the degradation on the frequency response functions for a specific layer of the stack can be determined by introducing a degradation in a specific layer, for example using equation 4, measuring the phase shift associated with this degradation using the Z(s) estimation of equation 3, and plotting a bode diagram as in FIGS. 5 to 7.

As an example, one or several frequencies between 20 Hz to 500 Hz are used to monitor the degradation on the layer 4 according to FIG. 6 and one or several frequencies between 1 Hz to 10 Hz are used to monitor the layer 10 resulting in the curve of FIG. 7.

In the case of a combination of several degradations, monitoring of the time delay at several frequencies enables to separate the contributions of the several degradations as in the example of FIG. 5.

To support the relation between Δt and the phase angle, as a first approximation, the change of phase angle Ph in angular unit of degrees (°) due to the degradation, that is the change from Δt=tp to Δt=td can be approximated by the following equation:

$$P h = ( t d - tp ) \cdot {f}_{f} \cdot 360. \qquad ( 7 )$$

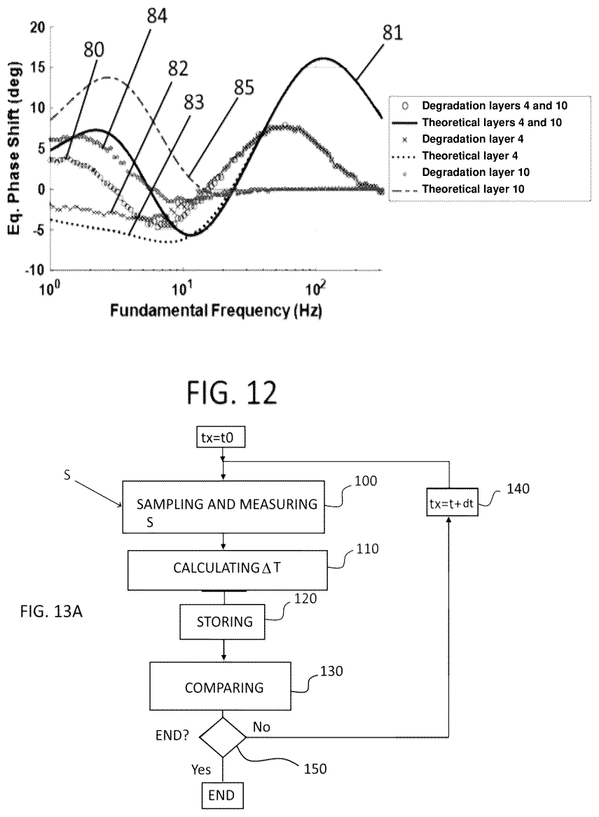

FIG. 12 shows a comparison of first-order estimation of the phase Ph using equation (7), and the phase extracted from calculations using the impedance method with respect to the fundamental frequency. In this diagram, curve 80 is the estimated phase curve for degraded layers 4 and 10 of FIG. 1 while curve 81 is the theoretical curve for such degraded layers, curve 82 is the estimated phase curve for degraded layer 4 while curve 83 is the theoretical curve fir such degraded layer, curve 84 is the estimated phase curve for degrade layer 10 and curve 85 the theoretical curve for such degraded layer 10. This shows that for frequencies above around 10 Hz, the first order estimation shows similar trend as the more rigorous model, thus demonstrating that the information in Δt is the same as in the phase of the bode diagrams of FIGS. 5 to 8.

Then, in case the fundamental frequency f of the AC current may be changed, the process may monitor the time difference for different fundamental frequencies. This gives a possibility to provide estimation of which of the layers are degraded layers.

As the time difference Δtmin between two successive minima of the junction temperature is measured, the fundamental frequency may be calculated as f_{fund}=1/Δtmin.

Thus, advantageously, this allows to record the fundamental frequency without using an additional sensor, or without acquiring the fundamental frequency information from a separate algorithm. Thus, advantageously, the algorithm for degradation analysis can work independently of a control algorithm of the converter or any other operating condition of the power module.

In example, in FIG. 10A, the time interval between two successive minima is Δtmin=0.02 s, and thus the fundamental frequency is found as f_{fund}=1/Δtmin=50 Hz.

The signal used for measuring the temperature may be any thermal sensitive electrical parameter (TSEP) of the concerned semiconductor switch.

Thus, the deterioration can be identified and quantified without any complex prior TSEP calibration, reducing the complexity of the system.

For example, the TSEP can have values X between Xa and Xb corresponding, for example to the range of temperature [−20 C;200 C], and the relation between the temperature and the TSEP is linear such as:

T=XA+B in [Xa;Xb] where A and B are constant.

In this example, it is not necessary to calibrate the TSEP, i.e., to determine A and B before implementing the method since only the variable X is measured. In a sub example, A>0, and the moments tTjmax and tTjmin where the junction temperature is at the maximum correspond to the moments where X is at the maximum, respectively at the minimum value. In another sub example, A<0, and the moments tTjmax and tTjmin where the junction temperature is at the maximum correspond to the moments where X is at the minimum, respectively at the maximum value.

More generally, it is sufficient that the function T(X) is monotonously increasing or decreasing, e.g., that its first derivative does not change sign in the interval [Xa;Xb]. Thus, advantageously non-calibrated TSEP with a non-linear temperature characteristic can also be used in the scope of the present disclosure.

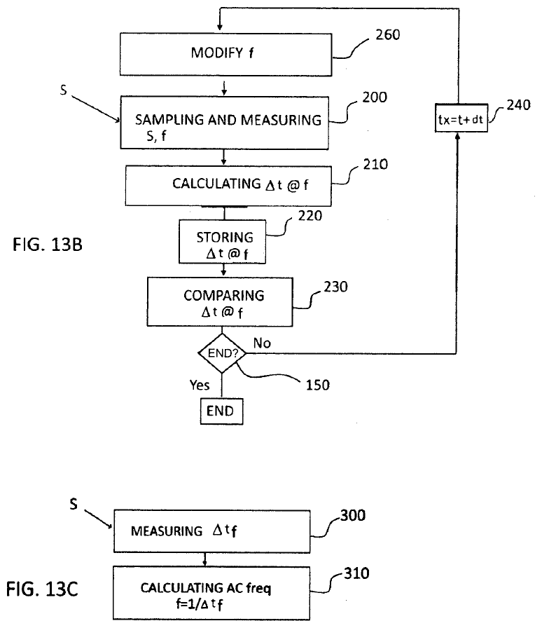

In FIG. 13A are shown process steps of the present disclosure with the process comprising:
Step 100: sampling and measuring a signal S relating to the junction temperature Tj of said semiconductor die at a frequency higher than ten time said AC frequency of said AC current 100,
Step 110 calculating a time duration Δt=tTjmax−tTjmin between a moment tTjmax, where said junction temperature of said semiconductor die is at a maximum value, and a moment tTjmin, where said junction temperature is at a minimum value, in one period of said AC current, and step 120 storing said time duration Δt in a memory,
Step 130 comparing said time durations Δtₜ₀ to Δtₜₚ for t=t₀ to tₚ values for monitoring an evolution of said time duration Δt to determine an evolution of degradation of the thermal impedance of said power module;
repeating 140, 150 said sampling and measuring said signal and said calculating said time duration at different times tₓ=t₀ to tₚ during the operating life of the power module to provide a series of time durations Δtₜ₀ to Δtₜₚ.

Step 100 may also comprise measuring said AC frequency and step 120 may comprise storing couple of time duration Δtₜₓ and AC frequency, f_{fund} values.

Measuring in step 100 may be done with several means such as thermocouple, infrared image, TSEP etc.

Since there may be some noise in the measurements, averaging of the Δt values may be required and the comparison may not be done strictly with the first Δt₀ value measured, but rather with a mean value over a measurement period of a few alternances at the beginning of the product usage. In such case, the averaging may be done on about two to ten alternances.

Repetition of the sampling, measuring and the comparison maybe done on a regular basis that is every day, week, month or after a number of alternances of the AC frequency corresponding to the use of the converter (e.g., tenth or hundreds of hours) relevant with the estimated degradation rate. Repetition rate may also be accelerated when a difference between Δtₜₓ and Δt₀ becomes larger than a predetermined warning value.

The process may also comprise as shown in FIG. 13B one or more steps 260 of modifying said AC frequency during dedicated operation periods of said converter to provide several different AC frequencies fₘ=f₁, f₂, . . . , fₙ each allowing to detect a thermal impedance of a specific layer of said stack up, repeating said sampling, and measuring the TSEP signal S and the frequency 200 and said calculating 210 the time durations Δt_{txf1}, Δt_{txf2}, . . . , Δtₜₓfₙ corresponding to such different AC frequencies,
one or more steps 230 of comparing said Δtₜ₀fₘ to Δtₜₚfₘ values at each of said AC frequencies for monitoring an evolution of Δt for each of said AC frequencies to determine an evolution of degradation of the thermal impedance of said specific layers,
repeating said sampling and measuring said signal and said calculating said time duration during the operating life of the power module to provide a series of Δtₓ=Δt₀ to Δtₚ values for each of said different AC frequencies fₘ for comparing the Δtₓ values with the Δt₀ value.

Here also, repetition of the sampling, measuring and the comparison maybe done on a regular basis that is every day, week, month or after a number of alternances of the AC frequency corresponding to the use of the converter (e.g., tenth or hundreds of hours) relevant with the estimated degradation rate. Repetition rate may also be accelerated when a difference between Δtₜₓ and Δt₀ becomes larger than a predetermined warning value.

In addition, the tests using adaptation of the AC frequency may be done in specific situations such as tests on the grid frequency or ramping of a motor speed.

The process also may comprise as in FIG. 13C one or more steps 300 of measuring a time difference Δtmin between two successive minima of the junction temperature and calculating 310 said AC frequency as f=1/Δtmin. This avoids having to measure the frequency with another means than the signal S relating to the junction temperature Tj which may be a non-calibrated temperature sensitive electrical parameter of said semiconductor.

To proceed with the present process the converter as shown in FIG. 9 may comprise sensor means 53 on a power semiconductor switch die of said converter for sensing a TSEP signal of said power semiconductor switch die, analog to digital converter means 54, sampling means 55 and a processor 56 provided with the necessary memory means 57 and computing means for storing and running a software configured for executing the thermal impedance monitoring process of the present disclosure.

1. Thermal impedance monitoring process for a power module of a power converter used for transforming DC current to AC current, or vice-versa, where the semiconductor dissipates an asymmetrical loss between two half cycles of an AC frequency f of the AC current, said power module comprising at least a semiconductor die attached to a material stack-up of layers for its thermal dissipation and/or electrical connections, said process comprising:
sampling and measuring a signal relating to the junction temperature Tj of said semiconductor die at a frequency higher than ten time said AC frequency of said AC current,
calculating a time duration Δt=tTjmax−tTjmin between a moment tTjmax, where said junction temperature of said semiconductor die is at a maximum value, and a moment tTjmin, where said junction temperature is at a minimum value, in one period of said AC current, and storing said time duration Δt in a memory,
repeating said sampling and measuring said signal and said calculating said time duration at different times tₓ=t₀ to tₚ during the operating life of the power module to provide a series of time durations Δtₜ₀ to Δtₜₚ, and comparing said time durations Δtₜₚ values with Δtₜ₀ for monitoring an evolution of said time duration Δtₓ to determine an evolution of degradation of the thermal impedance of said power module.

2. The thermal impedance monitoring process according to claim 1 comprising averaging the Δt measurements on periods for reducing noise in the measurements.

3. The thermal impedance monitoring process according to claim 1 comprising measuring said AC frequency and storing couple of time duration Δtₜₓ and AC frequency, f_{fund} values.

4. The thermal impedance monitoring process according to claim 3 comprising modifying said AC frequency during dedicated operation periods of said converter to provide several different AC frequencies fₘ=f₁, f₂, . . . , fₙ each allowing to detect a thermal impedance of a specific layer of said stack up, repeating said sampling, and measuring and said calculating the time durations Δtₜₓfₘ=Δt_{txf1}, Δt_{txf2}, . . . , Δt_{txfn} corresponding to such different AC frequencies,
repeating said sampling and measuring said signal and said calculating said time duration during the operating life of the power module to provide a series of Δ_{t0fm} to Δ_{txfm} values for each of said different AC frequencies, and comparing said Δtₜₘ values with Δtₜ₀ at each of said AC frequencies for monitoring an evolution of Δt for each of said AC frequencies fₘ=f₁, f₂, . . . , fₙ to determine an evolution of degradation of the thermal impedance of said specific layers.

5. The thermal impedance monitoring process according to claim 3 comprising measuring a time difference Δtmin between two successive minima of the junction temperature and calculating said AC frequency as f=1/Δtmin.

6. The thermal impedance monitoring process according to claim 1 wherein the signal relating to the junction temperature Tj is a temperature sensitive electrical parameter of said semiconductor.

7. The thermal impedance monitoring process according to claim 6 wherein the signal relating to the junction temperature Tj is a non-calibrated temperature sensitive electrical parameter of said semiconductor.

8. The thermal impedance monitoring process according to claim 1 wherein said AC frequency is lower than
$${f}_{d} = \frac{{D}_{die}}{{l}_{die}^{2}}$$
where l_{die} is the die thickness and D_{die} is the diffusivity coefficient of the die.

9. The thermal impedance monitoring process according to claim 1 wherein said AC frequency is lower than 2 kHz.

10. The thermal impedance monitoring process according to claim 1 wherein said AC frequency is lower than 1 kHz.

11. The thermal impedance monitoring process according to claim 1 wherein said AC frequency is the fundamental frequency powering the converter or the fundamental output frequency f_{fund} of the converter.

12. Converter comprising a sensor on a power semiconductor switch die of said converter for sensing a temperature of said power semiconductor switch die, an analog to digital converter, a sampler and a processor provided with a memory for storing and running a software configured for executing the thermal impedance monitoring process according to claim 1.

13. The converter according to claim 12 wherein said sensor being designed to sense a temperature sensitive electrical parameter of said power semiconductor switch die.

14. Permanent memory comprising a software comprising instructions for executing the thermal impedance monitoring process according to claim 1 when executed by a processor.
